(19) United States
(12) Patent Application Publication
(10) Pub. No.: US 2007/0161167 A1
(43) Pub. Date: Jul. 12, 2007

(54) Fabrication method of display device

(75) Inventors: Jun Gotoh, Mobara (JP); Akio Kawano, Mobara (JP)

Correspondence Address: Stanley P. Fisher;Reed Smith LLP, 3110 Fairview Park Drive, Suite 1400, Falls Church, VA, 22042-4503, US

(73) Assignee: Hitachi Displays, Ltd.

(21) Appl. No.: 11/600,727

(22) Filed: Nov. 17, 2006

(30) Foreign Application Priority Data
Jan. 11, 2006 (JP) 2006-003580

(51) Int. Cl. H01L 21/84

(52) U.S. Cl. 438/162; 438/164

(57) ABSTRACT

Non-uniformity of the sheet resistance associated with ion implantation into a polysilicon semiconductor layer using a ribbon-shaped beam is minimized to prevent variations in the characteristics of fabricated thin film transistors. When the implanted ions are of a first element, a second element that is heavy and has no influence on electric charge is implanted at a critical implantation quantity or more into a dose region of the polysilicon semiconductor layer into which the ions of the first element are implanted.

### BACKGROUND OF THE INVENTION

The present invention relates to a fabrication method of a display device in which the sheet resistance of a low-temperature polysilicon semiconductor layer deposited on an insulating substrate is made uniform after ion implantation is performed for the low-temperature poly-silicon semiconductor layer.

Flat panel display devices that perform active matrix driving include a display device for a display monitor capable of performing-high-resolution and color display, a liquid crystal display device for a television receiver that uses a liquid crystal panel as the display panel, and an organic electroluminescent display device (an organic EL display device) that uses an electroluminescent (especially organic electroluminescent) element. These flat panel display devices have been already in practical use or in the stage of development for practical use.

The flat-panel display device of this type has a display region in which a multiplicity of pixels comprising active elements such as thin film transistors are arranged in matrix on an insulating substrate made of, for example, glass. In addition, what is called a system-in-panel has also been developed, in which a scanning signal driving circuit and a video signal driving circuit for driving the pixels as well as other peripheral circuits are directly packaged around the display region. This kind of insulating substrate in which various thin film transistor circuits are formed therein is also referred to as a thin film transistor (TFT) substrate or an active matrix substrate. In the following description, this type of substrate is called a TFT substrate or also simply a substrate.

In the case where a thin film transistor circuit is packaged on a substrate that makes up a flat-panel display device, an amorphous silicon semiconductor layer is deposited on the substrate, and the amorphous silicon semiconductor layer is annealed to form a polysilicon semiconductor layer. Then, ions of an impurity element are implanted in a desired portion of this polysilicon semiconductor layer to form channel regions as well as source and drain regions of the thin film transistors. When such ion implantation is applied to a large-sized substrate of a display panel for, for example, a display monitor or a television receiver, the ion implantation into the polysilicon semiconductor layer deposited on the large-sized substrate can be carried out in a short time by scanning the substrate area with a ribbon-shaped (or a belt-shaped) ion beam. Because the ion beam has a positive charge, the ion beam is neutralized by supplying electrons when irradiating the substrate. Herein, the ion beam that has been neutralized by being supplied with electrons is also simply referred to as a beam.

FIG. 6 is a diagram for illustrating the process of ion implantation for the low-temperature polysilicon semiconductor layer deposited on a large-sized substrate. A low-temperature polysilicon semiconductor layer PSI formed on a large-sized substrate SUB is irradiated with a ribbon-shaped beam B. A scanning direction S for the irradiation with the ribbon-shaped beam B is a direction Y that intersects a longitudinal direction X of the ribbon-shaped beam B. In the case where the ribbon-shaped beam B is shaped into an ideal configuration, in other words, when the current density of the ribbon-shaped beam is uniform within the ribbon-shaped configuration, both the current value and the current density of the beam are uniform within the substrate SUB. The low-temperature polysilicon semiconductor layer is amorphized (turned into amorphous silicon) due to implantation damages by the ions, and the amorphous silicon is recrystallized in a subsequent annealing step and turned into polysilicon. At this stage, the ions are taken into the crystal lattices of the silicon semiconductor layer to activate the semiconductor layer.

FIG. 7 shows graphs for illustrating distributions across a substrate of the beam current, of the current density, of the degree of amorphization of the low-temperature polysilicon semiconductor layer, and of the sheet resistance of the polysilicon semiconductor layer, in the case of a beam with an ideal shape. FIGS. 7A, 7B, 7C, and 7D represent respective distributions of the beam current value Ib, the beam current density Id, the degree of amorphization Dp, and the sheet resistance Rs of the low-temperature polysilicon semiconductor layer, along the X direction. As illustrated in FIG. 7A, a beam B with an ideal shape is formed, so that the current value and the current density (FIG. 7B) for the implantation also become constant (uniform) over the substrate area. The degree of amorphization (FIG. 7C) also becomes uniform, and the sheet resistance of the low-temperature polysilicon semiconductor layer after the ion implantation also becomes uniform as well as illustrated in FIG. 7D. However, it is difficult to form such an ideal beam shape with an actual ion implantation apparatus, and variations in the beam width exist.

### SUMMARY OF THE INVENTION

When ion implantation is performed for a low-temperature polysilicon semiconductor layer deposited on a large-sized substrate using a ribbon-shaped ion beam, the non-uniformity of the current density distribution in the ribbon-shaped ion beam causes non-uniformity of the sheet resistance distribution in the low-temperature polysilicon semiconductor layer even though the dosage of the ions is constant. As a result, the characteristics of the thin film transistors, such as their threshold voltage, vary depending on the locations where the thin film transistors are formed. This is discussed with reference to FIGS. 8 and 9.

FIG. 8 show views for illustrating the process of actual ion implantation for the low-temperature polysilicon semiconductor layer deposited on a large-sized substrate. The structure in FIG. 8 is the same as that in FIG. 6 except the beam shape is in a wedge-shaped configuration.

FIG. 9 shows graphs for illustrating distributions across a substrate of the beam current, of the current density, of the degree of amorphization of the low-temperature polysilicon semiconductor layer, and of the sheet resistance of the low-temperature polysilicon semiconductor layer, in the case of an actual ion implantation apparatus. FIGS. 9A, 9B, 9C, and 9D represent respective distributions of the beam current value Ib, the beam current density Id, the degree of amorphization Dp, and the sheet resistance Rs of the low-temperature polysilicon semiconductor layer, along the X direction.

In the case that the shape of the implanted ion beam results in, as shown in FIG. 8, a wedge-shaped configuration with its center being thin because of some kind of equipment-originated factor, such as the shape of the ion source chamber, the current density of the ion beam becomes higher in the center part than in the peripheral part as shown in FIG. 9B even though the amount of current of the implanted ion beam is in a uniform distribution as shown in FIG. 9A. As a result, the degree of amorphization proceeds more greatly in the Y direction toward approximately the center part of the substrate with respect to the X direction than in the peripheral part with respect to the X direction as shown in FIG. 9C, and consequently, the low-temperature polysilicon semiconductor layer shows a lower sheet resistance in the center part with respect to the X direction after the activation annealing (FIG. 9D).

It is an object of the invention to provide a method of fabricating a display device in which characteristic variations in the thin film transistors formed therein are prevented, by minimizing the non-uniformity in the sheet resistance associated with the ion implantation into the low-temperature polysilicon semiconductor layer with the use of a ribbon-shaped beam.

In order to accomplish the foregoing object, the invention is characterized by implanting, where the implanted ions are of a first element, a second element at a critical implantation quantity or more into a dose region of the low-temperature polysilicon semiconductor layer in which the ions of the first element are implanted, the second element being heavy and having no influence on electric charge.

It is possible that boron ions (B⁺), for example, may be used as the first element and an inert gas (such as Ar, kr, and Xe) may be used as the second element.

The step of implanting the second element may be performed either before or after the implantation of the first element.

It is to be understood that the invention is not limited to these embodiments, and that various other modifications may be effected without departing from the scope of the invention.

Implanting the second element that is heavy and has no influence on electric charge imparts uniform damage to the polysilicon semiconductor layer, promoting amorphization. As a result, the activation rate of the first element implanted becomes uniform and efficient. Therefore, variations of the wiring resistance of the low-temperature polysilicon semiconductor layer reduce within the substrate area, and the sheet resistance also reduces.

Since the variations of the wiring resistance of the low-temperature polysilicon semiconductor layer reduces within the substrate area, variations in the characteristics of the thin film transistors formed in the low-temperature polysilicon semiconductor layer accordingly reduce. In addition, since the activation efficiency improves, it becomes possible to reduce the dosage in the ion implantation, enabling to improve the productivity.

### BRIEF DESCRIPTION OF THE DRAWINGS

FIGS. 1A through 1K are schematic cross-sectional views illustrating a fabrication process of a thin film transistor substrate according to embodiment 1 of the invention.

FIG. 2 is a diagram for illustrating an actual process of ion implantation for a low-temperature polysilicon semiconductor layer deposited on a large-sized substrate according to embodiment 1 of the invention.

FIGS. 3A through 3D are graphs for illustrating distributions across a substrate of the beam current, of the current density, of the degree of amorphization of the low-temperature polysilicon semiconductor layer, and of the sheet resistance in the low-temperature polysilicon semiconductor layer, in the case of an ion implantation apparatus according to embodiment 1 of the invention.

FIG. 4A is a cross-sectional view of the thin film transistor according to the invention, and FIG. 4B is a top view thereof.

FIG. 5 is a table listing the critical implantation quantities of elements that are implanted in the semiconductor layer in the invention.

FIG. 6 is a diagram for illustrating a process of ion implantation for the low-temperature polysilicon semiconductor layer deposited on a large-sized substrate.

FIGS. 7A through 7D are graphs for illustrating distributions across a substrate of the beam current, of the current density, of the degree of amorphization of the low-temperature polysilicon semiconductor layer, and of the sheet resistance of the polysilicon semiconductor layer, in the case of a beam with an ideal shape.

FIG. 8 is a diagram for illustrating an actual process of ion implantation for a low-temperature polysilicon semiconductor layer deposited on a large-sized substrate.

FIGS. 9A through 9D are graphs for illustrating distributions across a substrate of the beam current, of the current density, of the degree of amorphization of the low-temperature polysilicon semiconductor layer, and of the sheet resistance in the low-temperature polysilicon semiconductor layer, in the case of an actual ion implantation apparatus.

### DESCRIPTION OF THE PREFERRED EMBODIMENTS

Hereinbelow, preferred embodiments of the invention are described with reference to the drawing illustrating the embodiments. In the following description, the insulating substrate on which a semiconductor layer is formed is assumed to be a thin film transistor substrate for a large-sized display panel. It should be noted that the low-temperature polysilicon semiconductor layer may also be referred to simply as a polysilicon semiconductor layer.

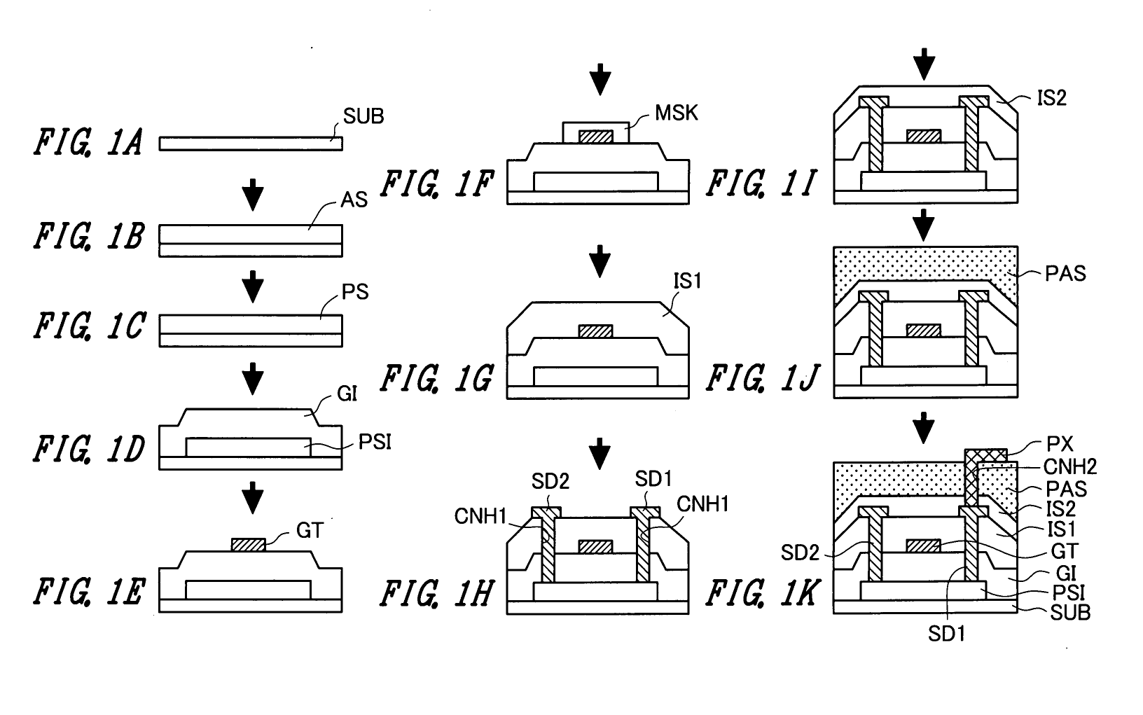

FIG. 1 shows schematic cross-sectional views for a major part illustrating a fabrication process of a thin film transistor substrate according to embodiment 1 of the invention. On a glass substrate SUB shown in FIG. 1A, an amorphous silicon semiconductor layer AS is deposited (FIG. 1B). This amorphous silicon semiconductor layer AS is annealed by being irradiated with a laser, preferably an excimer laser, so that the amorphous silicon semiconductor layer is crystallized to form a polysilicon semiconductor layer PS (FIG. 1C). The polysilicon semiconductor layer PS is subjected to a photolithography process so that a polysilicon semiconductor layer island PSI is left in the location where a thin film transistor form is to be formed. A gate insulating layer GI is deposited so as to cover this island (FIG. 1D).

A gate electrode GT is patterned at the center portion of the island PSI on the gate insulating layer GI. Using the gate electrode GT as a mask, an LDD ion implantation is performed (FIG. 1E). Next, a mask MSK is formed so as to cover the gate electrode GT (FIG. 1F). This mask MSK is formed so as to cover the gate electrode GT and also to avoid source and drain regions in the island PSI of the polysilicon semiconductor layer. By performing ion implantation in this state, ions are implanted in the source and drain regions in the island PSI. It is desirable to implant the second element of the invention at this stage.

The mask MSK is removed, and silicon oxide SiO₂ is deposited as an interlayer film IS1. Then, annealing for activating the island PSI is carried out. At this time, recrystallization is effected (FIG. 1G). Contact holes CNH1 are processed piercing through the interlayer film IS1 and the gate insulating layer GI and reaching the source region and the drain region of the island PSI. Then, a source electrode SD1 and a drain electrode SD2 are formed. The source electrode SD1 and the drain electrode SD2 bury these contact holes CNH1, and one end of each of the source electrode and the drain electrode is exposed on the surface of the interlayer film IS1 (FIG. 1H). The drain electrode SD2 is connected to a drain wire (data line).

Silicon nitride SiN is deposited over the source electrode SD1 and the drain electrode SD2 to form a protection layer IS2 (FIG. 1I). Furthermore, an organic passivation layer PAS is deposited on top of the protection layer IS2 (FIG. 1J). A contact hole CNH2 is formed piercing through the organic passivation layer PAS and the protection layer IS2, and reaching the source electrode SD1. An ITO is deposited on top of the organic passivation layer PAS so that the ITO is connected to the source electrode SD1 through the contact hole CNH2, to thus form a pixel electrode PX (FIG. 1K).

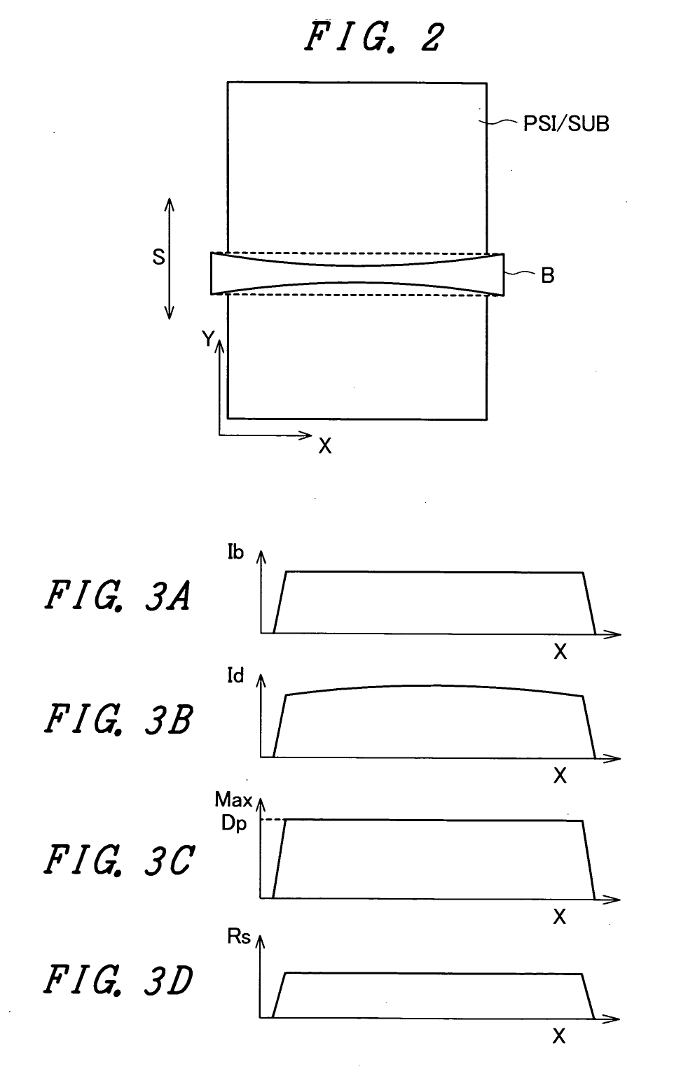

FIG. 2 is a diagram for illustrating the process of the actual ion implantation for the low-temperature polysilicon semiconductor layer deposited on a large-sized substrate, according to embodiment 1 of the invention. The structure shown in FIG. 2 is the same as that in FIG. 9.

FIG. 3 shows graphs for illustrating distributions across a substrate of the beam current, of the current density, of the degree of amorphization of the low-temperature polysilicon semiconductor layer, and of the sheet resistance of the low-temperature polysilicon semiconductor layer, in the case of an ion implantation apparatus according to embodiment 1 of the invention. FIGS. 3A, 3B, 3C, and 3D represent respective distributions of the beam current value Ib, the beam current density Id, the degree of amorphization Dp, and the sheet resistance Rs of the low-temperature polysilicon semiconductor layer, along the X direction. In the case where the shape of beam B deviates from an ideal shape and becomes a wedge-shaped configuration with its beam width being narrow toward the center along the longitudinal direction of the beam as shown in FIG. 2, the distribution of the beam current density Id becomes larger toward the center as shown in FIG. 3B even when the distribution of the beam current value Ib is constant as shown in FIG. 3A.

In the invention, however, after the implantation of the first element, argon ions Ar⁺ are implanted as the second element at a critical implantation quantity (CIQ) shown in FIG. 5 (4×10¹⁴ cm⁻²) or more, whereby amorphization is allowed to proceed so that the degree of amorphization Dp reaches maximum (Max), as shown in FIG. 3C. In other words, by implanting the second element, the polysilicon semiconductor layer that has been in a polycrystalline state is brought back completely into an amorphous state. This allows the distribution of the degree of amorphization Dp along the X direction to become uniform while the degree of amorphization stays at the maximum (Max). Therefore, the distribution of the sheet resistance Rs shows no variation and becomes uniform along the X direction as shown in FIG. 3D after recrystallization is effected in the subsequent activation annealing step.

For example, in the conventional case of FIG. 9C, merely boron ions B⁺ were implanted at 1×10¹⁵ cm⁻². This means that the implantation quantity of boron ions did not reach the critical implantation quantity of boron shown in FIG. 5 (2×10¹⁶ cm⁻²), and the degree of amorphization Dp did not reach the maximum (Max) (i.e., amorphization was incomplete). As a result, the distribution of degree of amorphization Dp also showed variations. The greater the degree of amorphization Dp becomes, the less the sheet resistance Rs after the recrystallization; therefore, the distribution shown in FIG. 9D resulted. For example, in the case where the activation was performed at 500° C., the sheet resistance was 3.5 kΩ/square where it was small and 4.5 kΩ/square where it was large.

In contrast, according to the invention, boron ions B⁺ were implanted as the first element at 1×10¹⁵ cm⁻², and thereafter, argon ions Ar⁺ were implanted as the second element at a critical implantation quantity or more, 5×10¹⁴ cm⁻². As a result, the polysilicon semiconductor layer was completely made amorphous as shown in FIG. 3C, and the sheet resistance Rs became approximately uniform at about 2.5 kΩ/square as shown in FIG. 3D after the subsequent recrystallization. This means that variations of the sheet resistance Rs reduced and also the sheet resistance Rs itself became less than the conventional case. It should be noted that argon ions Ar⁺ may be implanted before boron ions B⁺ are implanted instead of after boron ions B⁺ are implanted. In this case as well, it was found that substantially the same advantageous effect was obtained.

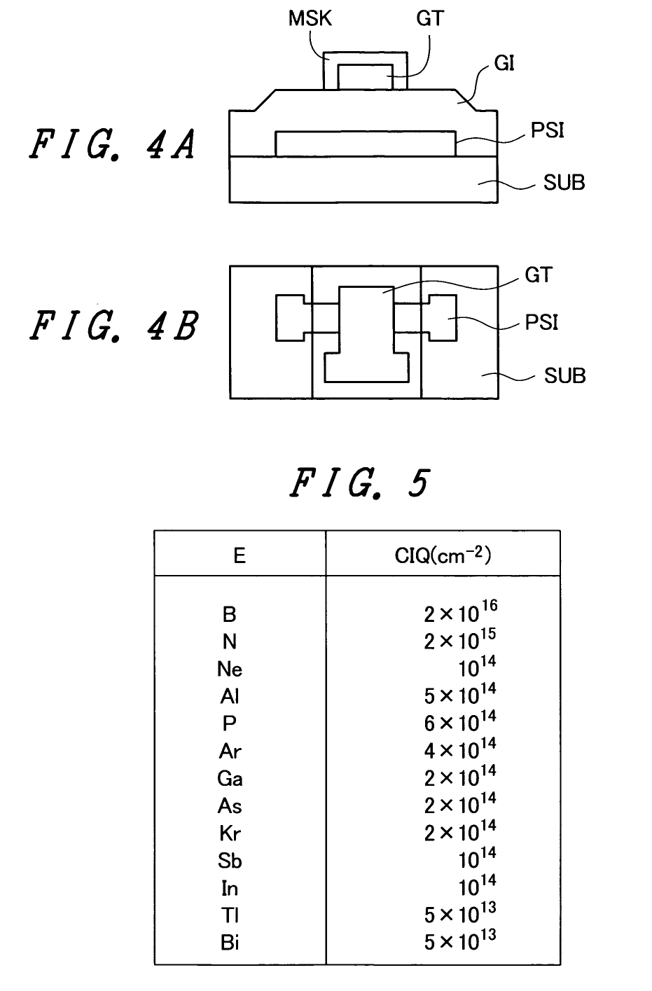

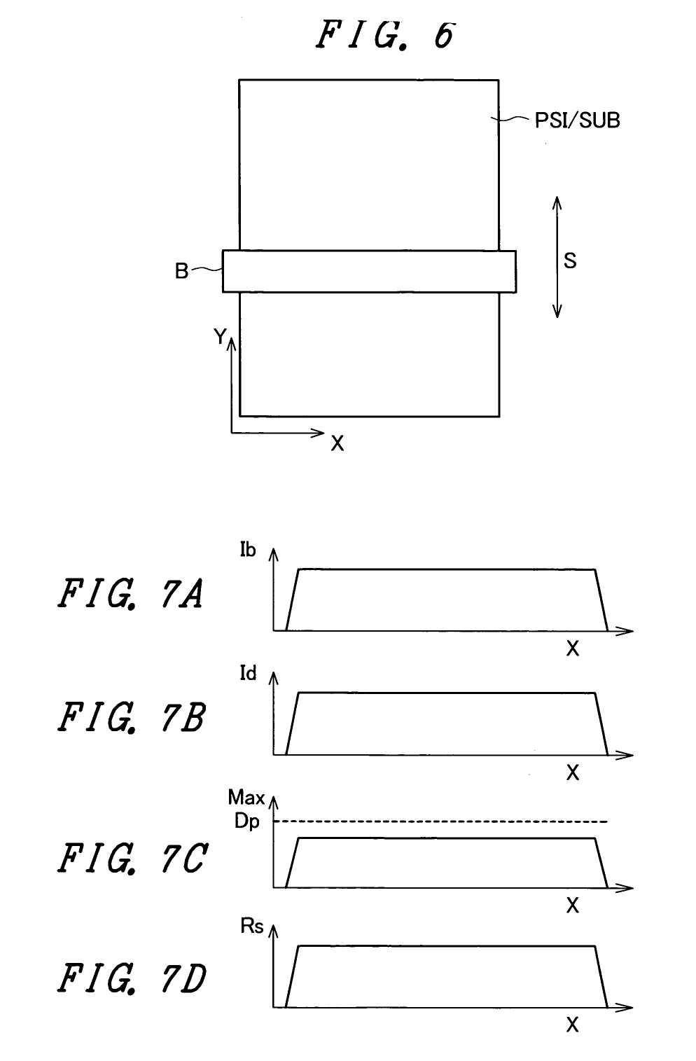

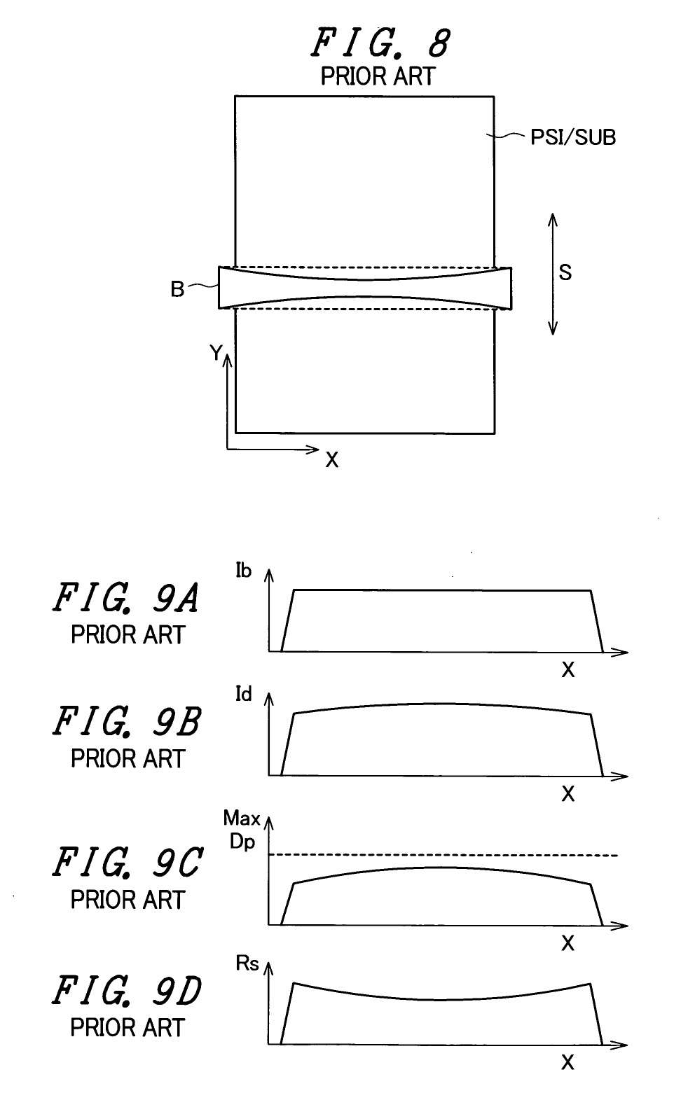

FIG. 4 show schematic views for illustrating an implantation process of the first element and the second element into the polysilicon semiconductor layer according to the invention. This process is at the stage of the implantation shown in FIG. 1F. FIG. 4A is a cross-sectional view, and FIG. 4B is a plan view of FIG. 4A, which show the state in which the gate electrode GT has been formed on the gate insulating layer GI.

FIG. 5 is a table that lists the critical implantation quantities (CIQ) at which the amorphous state is effected at room temperature, of the elements (E) that may be implanted into the semiconductor layer according to the invention. In the foregoing embodiment, boron B was used as the first element and argon Ar was used as the second element. In addition to these elements, various elements listed in FIG. 5 may be used.

The invention is not limited to the process that is illustrated in FIG. 1. For example, the invention is applicable to a method in which ion implantation is performed to form the source and drain regions while the photomask for etching the gate electrode is left unremoved and subsequently ion implantation for LDD regions is performed after removing the photomask. In this case, it is preferable that the invention is applied to the ion implantation for forming the source and drain regions.

It is preferable that the second element is an element having an atomic weight heavier than that of the first element, which determines the conductivity type. An element having a greater atomic weight tends to show a less critical implantation quantity. Therefore, the dosage of the second element can be reduced, and high efficiency can be achieved. It is preferable to use an inert gas (such as argon, krypton, and xenon) as the second element. The reason is that the inert gas has no influence on electrical charge. In addition, the use of the second element makes it possible to bring the semiconductor completely into an amorphous state without increasing the dosage of the first element, and therefore achieves high efficiency.

The invention is not limited to the foregoing embodiments, and various modifications may be made without departing from the scope of the invention.

What is claimed is:

1. A method of fabricating a display device in which thin film transistors are formed by implanting ions into a polysilicon semiconductor layer deposited on an insulating substrate, the method comprising:
implanting, where the ions are of a first element, a second element at a critical implantation quantity or more into a dose region of the polysilicon semiconductor layer in which the ions of the first element is implanted, the second element being heavy and having no influence on electric charge.

2. The method of fabricating a display device according to claim 1, wherein the first element is boron, and the second element is an inert gas that is heavier than the first element.

3. The method of fabricating a display device according to claim 2, wherein the inert gas is one of argon, krypton, and xenon.

4. The method of fabricating a display device according to claim 1, wherein the step of implanting the second element is performed after implanting the first element.

5. The method of fabricating a display device according to claim 1, wherein the step of implanting the second element is performed before implanting the first element.
